(19) United States
(12) Patent Application Publication
(10) Pub. No.: US 2025/0205723 A1
(43) Pub. Date: Jun. 26, 2025

(54) MASK ASSEMBLY

(71) Applicant: Samsung Display Co., LTD., Yongin-si (KR)

(72) Inventor: SANGHA PARK, Yongin-si (KR)

(21) Appl. No.: 18/794,047

(22) Filed: Aug. 5, 2024

(30) Foreign Application Priority Data
Dec. 21, 2023 (KR) 10-2023-0188025

(51) Int. Cl. B05B 12/22; H10K 59/12; H10K 71/16

(52) U.S. Cl. CPC B05B 12/22; H10K 59/12; H10K 71/166

(57) ABSTRACT

A mask assembly includes: a mask frame having a frame opening defined therein; and a mask disposed on an upper surface of the mask frame and in which a clamp groove is defined on at least one of two sides opposite to each other in a first direction. The mask includes: a cell region having a deposition part and a dummy part extending in the first direction from the deposition part toward the clamp groove; and a peripheral region surrounding the cell region and having the clamp groove defined therein. An inner surface of the peripheral region, which defines the clamp groove, has a shape corresponding to an outer surface of the dummy part.

This application claims priority to Korean Patent Application No. 10-2023-0188025, filed on Dec. 21, 2023, and all the benefits accruing therefrom under 35 U.S.C. § 119, the content of which in its entirety is herein incorporated by reference.

### BACKGROUND

The present disclosure herein relates to a mask assembly.

A display device outputs a video or an image through a display region so as to provide various visual information to a user. An organic light-emitting display device among display devices has advantages of a wide viewing angle, an excellent contrast, and a fast response speed. A display region of such an organic light-emitting display device is composed of a plurality of pixels, and the plurality of pixels may form the display region through a process of depositing a deposition material.

A deposition apparatus may include a mask, a mask frame, and a stage. The mask may be stretched and fixed on the mask frame.

### SUMMARY

The present disclosure provides a mask assembly with a reduced amount of deformation of a mask when the mask is stretched and fixed on an upper surface of a mask frame.

An embodiment of the invention provides: a mask assembly including a mask frame having a frame opening defined therein; and a mask disposed on an upper surface of the mask frame, and in which a clamp groove is defined in at least one of two sides opposite to each other in a first direction, where the mask has: a cell region having a deposition part and a dummy part extending in the first direction from the deposition part toward the clamp groove, and a peripheral region surrounding the cell region and having the clamp groove defined therein, and an inner surface of the peripheral region, which defines the clamp groove, has a shape corresponding to an outer surface of the dummy part.

In an embodiment of the invention, a mask assembly includes: a mask frame having a frame opening defined therein; and a mask disposed on an upper surface of the mask frame, and having a plurality of protrusions disposed on at least one of two sides opposite to each other in a first direction, where the mask has: a deposition part; a dummy part extending from at least one of the two sides of the deposition part opposite to each other in the first direction, and a peripheral region surrounding the deposition part and the dummy part, and a clamp groove is defined between the protrusions arranged in a second direction crossing the first direction, and a ratio of an area of the dummy part to an area of the clamp groove, which is defined as a region closed by a first imaginary line extending in the second direction and connecting ends of the protrusions, is about 0.95 to about 1.05 in a plan view.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a cross-sectional view of a deposition apparatus according to an embodiment of the invention;

FIG. 2A is a perspective view of a mask assembly illustrated in FIG. 1;

FIG. 2B is an exploded perspective view of the mask assembly illustrated in FIG. 2A;

FIG. 3 is a plan view of a mask illustrated in FIG. 2A;

FIG. 4 is a plan view of a mask according to another embodiment of the invention;

FIG. 5A illustrates that the mask illustrated in FIG. 3 has been deformed;

FIG. 5B is a cross-sectional view taken along line I-I′ illustrated in FIG. 5A;

FIGS. 6A to 6I illustrate masks according to Comparative Examples;

FIGS. 7A and 7B illustrate a mask according to another embodiment of the invention;

FIGS. 8A to 8F illustrate masks according to Comparative Examples;

FIGS. 9A and 9B illustrate a mask according to another embodiment of the invention;

FIGS. 10A to 10F illustrate masks according to Comparative Examples;

FIG. 11 is a plan view of a display panel manufactured using the mask assembly illustrated in FIG. 2A;

FIG. 12 exemplarily illustrates a cross-section of one pixel illustrated in FIG. 11; and

FIG. 13 illustrates a deposition process illustrated in FIG. 1.

### DETAILED DESCRIPTION

Advantages and features of the invention, and methods to achieve those will be clear when referring to the embodiments to be described later in detail with reference to the accompanying drawings. However, the invention will not be limited to the embodiments to be disclosed below and will be embodied in different and various forms. These embodiments are merely provided so that the disclosure of the invention will be thorough and complete, and will fully convey the scope of the invention to those skilled in the art. The invention is determined by the scope of the claims. Like reference numerals or symbols refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. The term “and/or” includes each of and all of one or more combinations of mentioned items.

Spatially relative terms, such as “below”, “beneath”, “lower”, “above”, “upper” and the like, may be used herein for ease of description to describe one element or component's relationship to another element(s) or component(s) as illustrated in the figures. It will be understood that the spatially relative terms are intended to encompass different orientations of the device in use or operation in addition to the orientation depicted in the figures. Like reference numerals or symbols refer to like elements throughout the specification.

It will be understood that, although the terms “first”, “second”, etc. may be used herein to describe various elements, components, and/or sections, these elements, components, and/or sections should not be limited by these terms. These terms are only used to distinguish one element, component, or section from another element, component or section. Thus, a first element, component, or section discussed below could be termed a second element, component, or section without departing from the teachings of the invention.

Embodiments described herein will be explained with reference to a plan view and a cross-sectional view which are ideal schematic diagrams of the invention. Accordingly, the form of illustrated examples may be modified by manufacturing technologies and/or tolerances, etc. Thus, embodiments of the invention are not limited to the specific shape as illustrated but include deformation generated by the manufacturing process. Therefore, regions illustrated in the drawings have schematic properties, and shapes of the regions illustrated in the drawings are intended to indicate specific shapes of the regions of elements, not to limit the scope of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not in preclude the presence or addition of one or more other features, regions, integers, steps, operations, elements, components, and/or groups thereof. Hereinafter, preferred embodiments of the invention will be described in more detail with reference to the accompanying drawings.

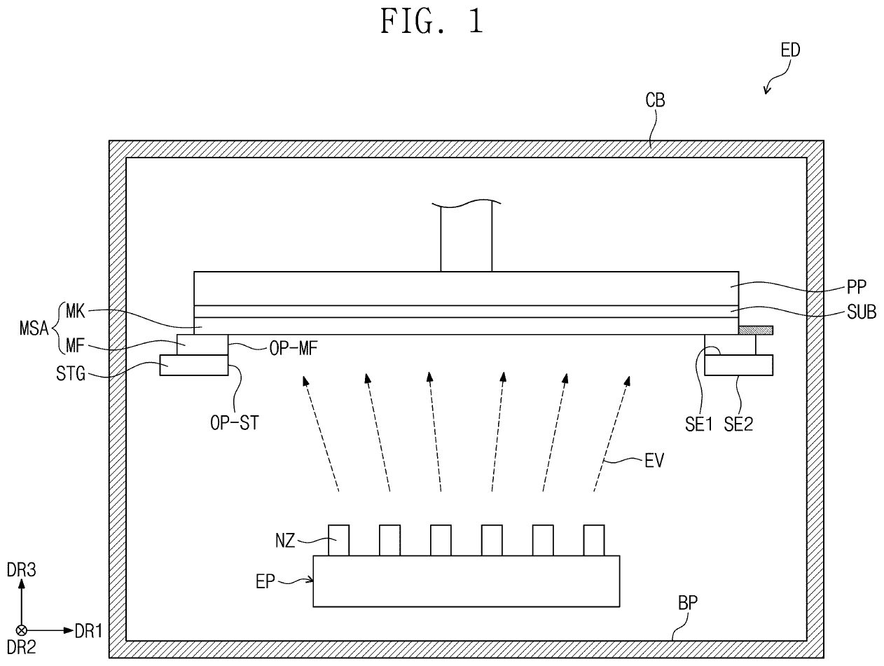

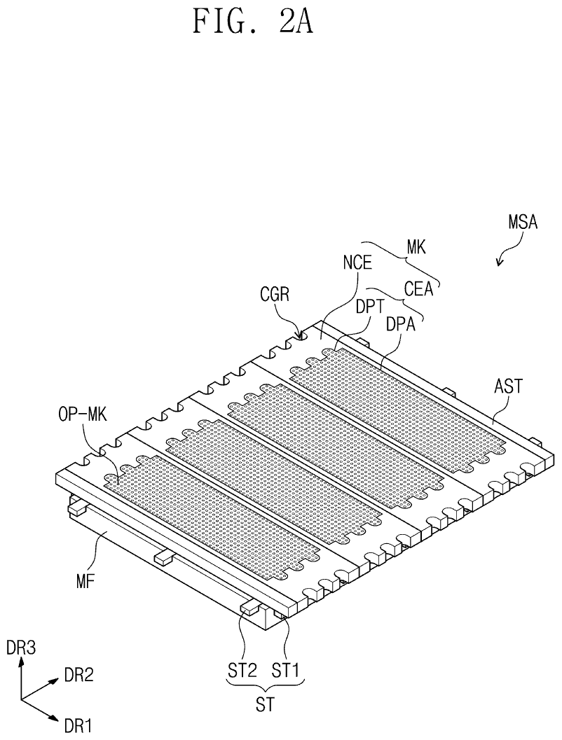

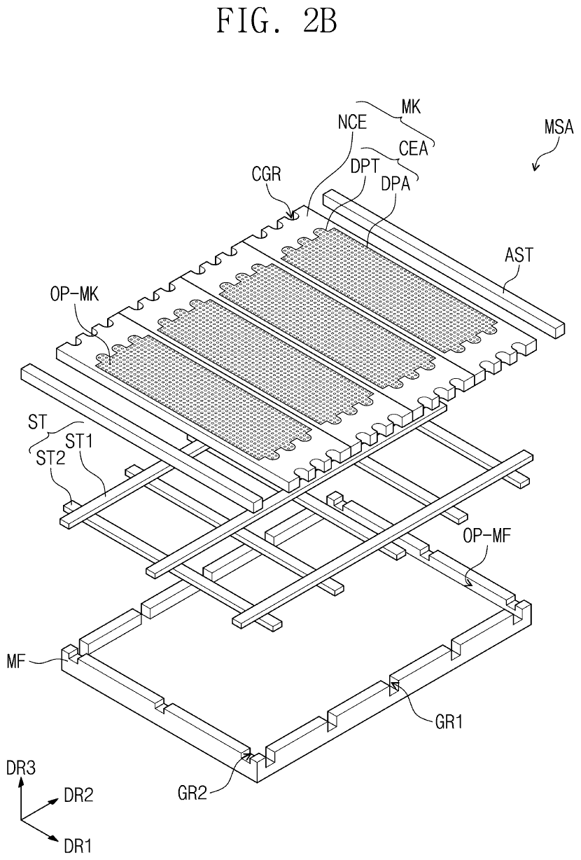

FIG. 1 is a cross-sectional view of a deposition apparatus according to an embodiment of the invention. FIG. 2A is a perspective view of a mask assembly illustrated in FIG. 1. FIG. 2B is an exploded perspective view of the mask assembly illustrated in FIG. 2A.

Referring to FIG. 1, a deposition apparatus ED according to an embodiment of the invention may include a chamber CB, a mask assembly MSA, a stage STG, a deposition source EP, and a fixing member PP. The mask assembly MSA may include a mask frame MF and a mask MK.

The chamber CB may provide an internal space, and the deposition source EP, the stage STG, the mask assembly MSA, and the fixing member PP may be disposed inside the chamber CB. The chamber CB may form a sealed space, and a deposition condition may be set to a vacuum. The chamber CB may provide at least one gate, and the chamber CB may be opened and closed through the gate. The stage STG, the mask assembly MSA, and a substrate SUB may enter and exit through the gate provided in the chamber CB.

The chamber CB may include a bottom surface BP, a ceiling surface, and side surfaces. The bottom surface BP of the chamber CB may be parallel to a plane defined by a first direction DR1 and a second direction DR2 crossing the first direction DR1.

Hereinafter, a direction crossing substantially perpendicularly to a plane, which is defined by the first direction DR1 and the second direction DR2, may be defined as a third direction DR3. In addition, in this specification, the wording “when viewed on a plane” (i.e., in a plan view) may be defined as a state viewed in the third direction DR3.

The fixing member PP may be disposed inside the chamber CB, and may face the deposition source EP in the third direction DR3. The fixing member PP may allow the substrate SUB to be adhered to the mask MK. The fixing member PP may include magnetic substances to allow the substrate SUB to be adhered to the mask MK. For example, the magnetic substances may fix the mask MK by generating magnetic force, and the substrate SUB disposed between the mask MK and the fixing member PP may be adhered to the mask MK. However, an embodiment of the invention is not limited thereto, and the fixing member PP may include a jig or a robot arm for holding the mask MK in another embodiment.

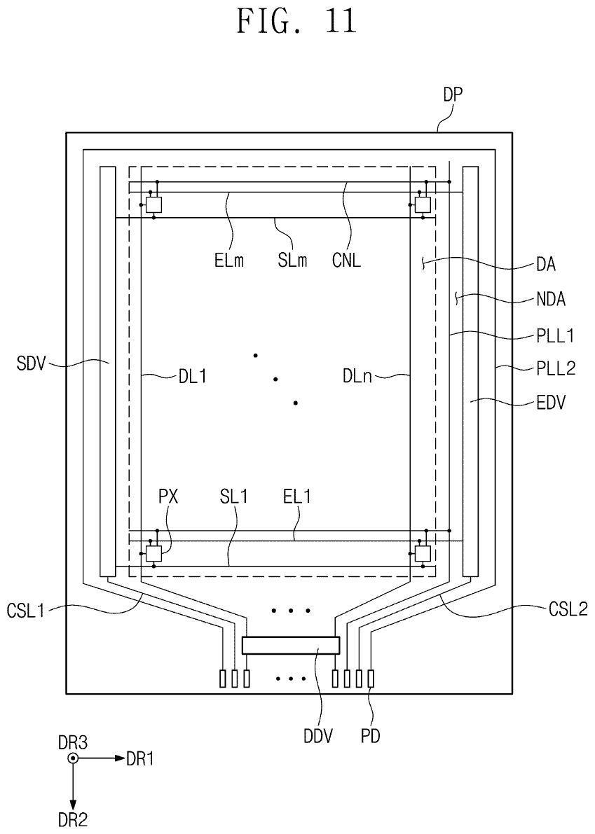

The substrate SUB may be disposed between the mask MK and the fixing member PP. The substrate SUB may be a processing target on which a deposition material is deposited. The substrate SUB may include a support substrate and a synthetic resin material disposed on the support substrate. The substrate SUB may include an organic light-emitting material to form a display panel DP (see FIG. 11). A deposition material EV which is sublimated or vaporized may be sprayed toward the substrate SUB through a nozzle NZ. The deposition material EV may be deposited on the substrate SUB through mask openings OP-MK (see FIG. 2B) of the mask MK.

The stage STG may be disposed between the deposition source EP and the fixing member PP. The stage STG may support a rear surface of the mask frame MF to be described later, and may be disposed in a movement path for the deposition material EV which is supplied to the substrate SUB from the deposition source EP. A stage opening OP-ST may be defined by the stage STG. The deposition material EV may be provided to the mask MK through the stage opening OP-ST.

The stage STG may include a seating surface SE1 and a rear surface SE2 facing the seating surface SE1. The seating surface SE1 and the rear surface SE2 of the stage STG may be surfaces parallel to the first direction DR1 and the second direction DR2. The seating surface SE and the rear surface SE2 of the stage STG may be provided substantially in parallel to the bottom surface BP of the chamber CB. Accordingly, rear surfaces of the mask frame MF and the mask MK, which are seated on the seating surface SE1 of the stage STG, may each be provided substantially in parallel to the bottom surface BP of the chamber CB, and thus a deposition process may proceed.

However, an embodiment of the invention is not limited thereto, and the seating surface SE1 and the rear surface SE2 of the stage STG according to an embodiment may be provided substantially perpendicular to the bottom surface BP of the chamber CB. The rear surfaces of the mask frame MF and the mask MK may each be provided substantially perpendicular to the bottom surface BP of the chamber CB, and thus a vertical deposition process may proceed.

Referring to FIGS. 1 to 2B, the mask frame MF may be disposed on the seating surface SE1 of the stage STG. The stage STG may support the mask frame MF. For example, two sides of the mask frame MF may be disposed inside more than two sides of the stage STG.

The mask frame MF may have a shape of a quadrangular frame which has short sides extending in the first direction DR1 and long sides extending in the second direction DR2. A frame opening OP-MF may be defined in the mask frame MF having a shape of a quadrangular frame. A shape of the frame opening OP-MF may be quadrangular.

As illustrated in FIG. 1, the frame opening OP-MF may overlap the stage opening OP-ST in a plan view. The frame opening OP-MF and the stage opening OP-ST may be defined sequentially in the third direction DR3.

First grooves GR1 and second grooves GR2 may be defined on an upper surface of the mask frame MF. The first grooves GR1 may extend from the upper surface of the mask frame MF toward a lower surface of the mask frame MF. For example, the first grooves GR1 may have a shape corresponding to a portion of a quadrangle.

When viewed on a plane, the first grooves GR1 may be arranged along the long sides of the mask frame MF in the second direction DR2. Intervals between the first grooves GR1 adjacent to each other in the second direction DR2 may be uniform.

The second grooves GR2 may extend from the upper surface of the mask frame MF toward the lower surface of the mask frame MF. For example, the second grooves GR2 may have a shape corresponding to a portion of a quadrangle.

In an embodiment, for example, the first grooves GR1 may extend toward the lower surface of the mask frame MF further than the second grooves GR2. For example, bottom surfaces of the first grooves GR1 may be closer to the lower surface of the mask frame MF than bottom surfaces of the second grooves GR2.

When viewed on a plane, the second grooves GR2 may be arranged along the short sides of the mask frame MF in the second direction DR2. Intervals between the second grooves GR2 adjacent to each other in the first direction DR1 may be uniform.

The mask frame MF may have predetermined rigidity. For example, the mask frame MF may include a metal material such as stainless steel (SUS), Invar, nickel (Ni), cobalt (Co), or the like.

The mask assembly MSA may further include rods ST. The rods ST may include first rods ST1 and second rods ST2. The first rods ST1 may be disposed on the upper surface of the mask frame MF. The first rods ST1 may be disposed in the first grooves GR1.

The first rods ST1 may extend in the first direction DR1, and may be arranged in the second direction DR2. The first rods ST1 may traverse the frame opening OP-MF. Central parts of the first rods ST1 may overlap the frame opening OP-MF. The first rods ST1 may pass through the first grooves GR1, and thus opposite ends of the first rods ST1 may be disposed outside the mask frame MF.

The second rods ST2 may be disposed in the second grooves GR2. The second rods ST2 may be disposed on the first rods ST1. The second rods ST2 may be disposed to cross the first rods ST1. For example, the second rods ST2 may be disposed directly on the first rods ST1. However, an embodiment of the invention is not limited thereto, and the first rods ST1 may be disposed on the second rods ST2 in another embodiment.

The second rods ST2 may be arranged in the first direction DR1, and extend in the second direction DR2. For example, lengths of the second rods ST2 in the second direction DR2 may be longer than lengths of the first rods ST1 in the first direction DR1. The second rods ST2 may traverse the frame opening OP-MF. Central parts of the second rods ST2 may overlap the frame opening OP-MF. The second rods ST2 may pass through the second grooves GR2, and opposite ends of the second rods ST2 may be disposed outside the mask frame MF.

The first rods ST1 and the second rod ST2 may include a non-magnetic material. For example, the first rods ST1 and the second rods ST2 may include aluminum. However, this is an example, and materials of the first rods ST1 and the second rods ST2 may not be limited thereto.

The masks MK may be disposed between the mask frame MF and the substrate SUB. The plurality of masks MK may be disposed on the upper surface of the mask frame MF. Two sides of the masks MK may be connected to the mask frame MF. The masks MK may extend in the first direction DR1 and may be arranged in the second direction DR2. The masks MK may have a rectangular shape having long sides extending in the first direction DR1 and short sides extending in the second direction DR2. A thickness direction of the mask MK is the third direction DR3.

In an embodiment, for example, the masks MK may be stretched in the first direction DR1 so as to cover the frame opening OP-MF. The stretched masks MK may be connected to the mask frame MF through laser welding.

The mask MK may be disposed on the first rods ST1 and the second rods ST2. The mask MK may not be detached from the mask frame MF by the first rods ST1 and the second rods ST2. That is, to prevent the masks MK from sagging due to gravity, the first rods ST1 and the second rods ST2 may serve as supports of the masks MK.

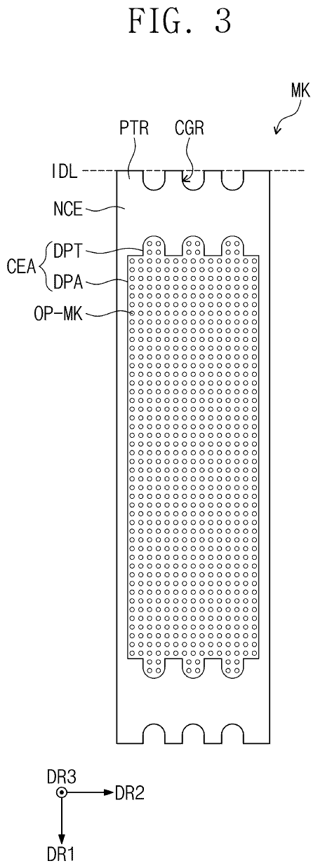

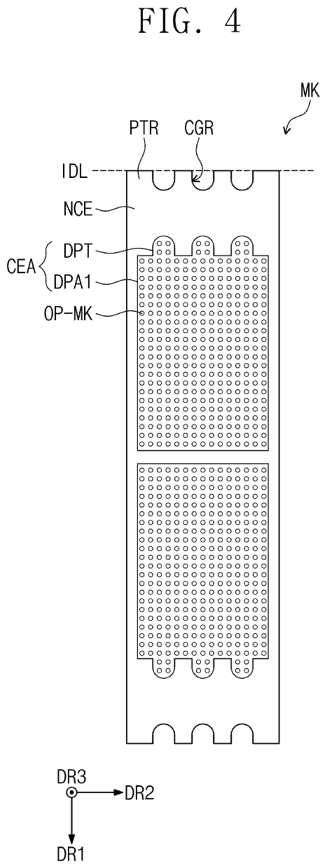

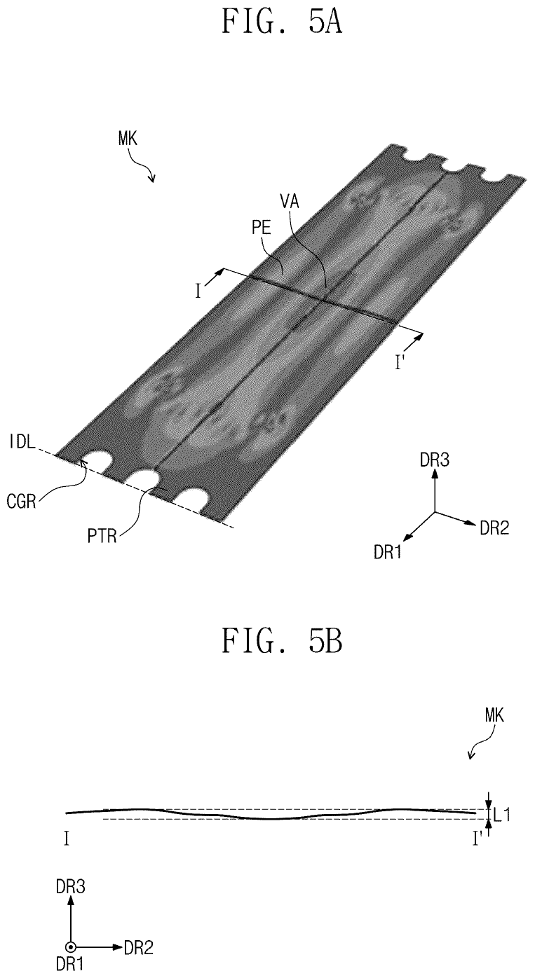

A plurality of clamp grooves CGR may be defined in two sides of the masks MK which are opposite to each other in the first direction DR1. For example, three clamp grooves CGR may be defined in each of ends of the masks MK, which are opposite to each other in the first direction DR1. The clamp grooves CGR may be recessed from the two sides of the masks MK toward the centers of the masks MK. The clamp grooves CGR will be described in detail with reference to FIG. 3.

The masks MK may have predetermined rigidity. For example, the masks MK may include a metal material such as stainless steel (SUS), Invar, nickel (Ni), cobalt (Co), or the like.

Cell regions CEA and peripheral regions NCE may be defined on upper surfaces of the masks MK. For example, one cell region CEA may be defined on the upper surface of the respective masks MK. However, the number of the cell regions CEA defined on the upper surface of the respective masks MK may not be limited thereto. The peripheral regions NCE may surround the cell regions CEA.

The cell regions CEA may overlap the frame opening OP-MF in a plan view. The cell regions CEA may overlap the stage opening OP-ST. The cell regions CEA may not overlap the mask frame MF in a plan view.

The cell regions CEA may not overlap the first rods ST1 in a plan view. The first rods ST1 may overlap the peripheral regions NCE which are disposed between the cell regions CEA adjacent to each other in the second direction DR2. The cell regions CEA may overlap the second rods ST2 in a plan view. The first rods ST1 and the second rods ST2 may overlap regions between the masks MK, thereby preventing a deposition material from being introduced to regions between the masks MK adjacent to each other.

The cell regions CEA may include a plurality of deposition parts DPA and a plurality of dummy parts DPT. For example, when viewed on a plane, the deposition parts DPA may be parallel to a plane defined by the first direction DR1 and the second direction DR2. The dummy parts DPT may extend in the first direction DR1 from two sides of the deposition parts DPA which are opposite to each other in the first direction DR1. Three dummy parts DPT may be disposed in each of one side and the other side of each deposition part DPA, but the number of the dummy parts DPT is not limited thereto.

The deposition parts DPA and the dummy parts DPT may not overlap the first rods ST1. The deposition parts DPA and the dummy parts DPT may overlap the second rods ST2 in a plan view. The dummy parts DPT will be described in detail with reference to FIG. 4.

A plurality of mask openings OP-MK may be defined in the cell regions CEA. The mask openings OP-MK may be defined in the dummy parts DPT and the deposition parts DPA. The mask openings OP-MK may be arranged in the first direction DR1 and the second direction DR2.

The mask openings OP-MK may overlap the frame opening OP-MF in a plan view. That is, the stage opening OP-ST, the frame opening OP-MF, and the mask openings OP-MK may be defined sequentially in the third direction DR3. Accordingly, as illustrated in FIG. 1, the deposition material EV may pass through the stage opening OP-ST, the frame opening OP-MF, and the mask openings OP-MK, and may be deposited on the substrate SUB.

The mask assembly MSA may further include a plurality of alignment rods AST. The alignment rods AST may be disposed on the upper surface of the mask frame MF. The alignment rods AST may be coupled to the upper surface of the mask frame MF through welding. The alignment rods AST may extend in the first direction DR1, and may be arranged in the second direction DR2. The masks MK may be disposed between the alignment rods AST. The alignment rods AST and the mask frame MF may be arranged in the second direction DR2.

The alignment rods AST may fix the positions of the masks MK with respect to the mask frame MF. The alignment rods AST may fix the masks MK so that the mask openings OP-MK and the frame openings OP-MF overlap each other in a plan view. However, in an embodiment, the alignment rods AST may be omitted.

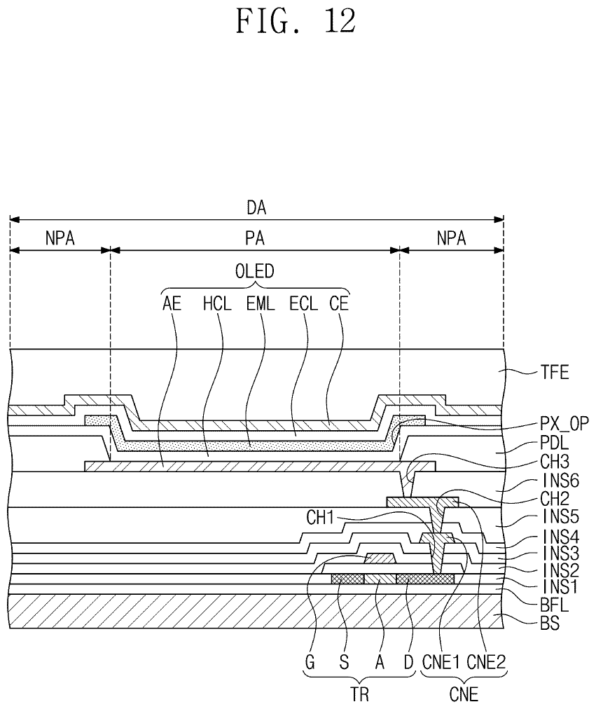

Referring to FIG. 1, the deposition source EP may be disposed inside the chamber CB and may face the fixing member PP in the third direction DR3. The deposition source EP may include a storage space in which the deposition material EV is accommodated, and at least one nozzle NZ. The deposition material EV may include a sublimable or vaporizable inorganic material, metal, or organic material. For example, the deposition material EV may include an organic light-emitting material for forming a light-emitting layer EML (see FIG. 12). The sublimated or vaporized deposition material EV may be sprayed toward the substrate SUB through the plurality of nozzles NZ. The deposition material EV may pass through the mask openings OP-MK of the mask MK and may be patterned and deposited on the substrate SUB.

The deposition apparatus ED may further include, in addition to the above configuration, an additional mechanical device for achieving an in-line system. The deposition apparatus ED according to an embodiment may further include a coupling member. The coupling member may be fixed to a side wall of the chamber CB, and the stage STG may be connected to the coupling member and stably fixed inside the chamber CB. Thus, a deposition process may be performed stably.

The deposition apparatus ED according to an embodiment may further include an alignment device. The alignment device may adjust the positions of the stage STG and the mask frame MF. Accordingly, it is possible to prevent defects from occurring when the deposition material EV passes through the stage opening OP-ST of the stage STG and the frame opening OP-MF of the mask frame MF and is deposited on the substrate SUB.

FIG. 3 is a plan view of the mask illustrated in FIG. 2A. FIG. 4 is a plan view of a mask according to another embodiment of the invention.

Since mask openings OP-MK in FIGS. 3 and 4 are the same as the mask openings OP-MK in FIGS. 2A and 2B, descriptions thereof will be omitted or simplified.

Referring to FIG. 3, clamp grooves CGR may be defined in both ends of a mask MK which are opposite to each other in the first direction DR1. The clamp grooves CGR may be arranged in the second direction DR2. For example, three clamp grooves CGR may be defined in each end of the masks MK, but the number of the clamp grooves CGR is not limited thereto.

Hereinafter, portions, of the mask MK, disposed between the clamp grooves CGR adjacent to each other in the second direction DR2 may be defined as protrusions PTR. The clamp grooves CGR may be defined by the protrusions PTR adjacent to each other in the second direction DR2.

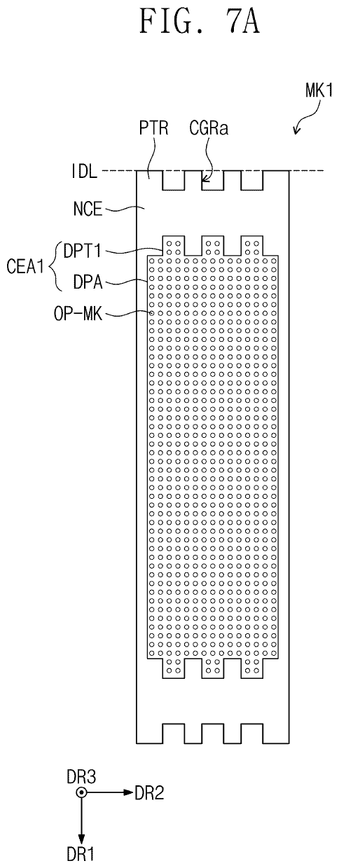

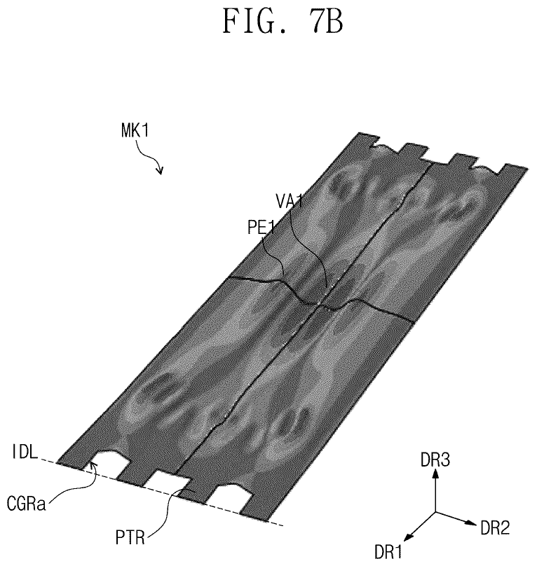

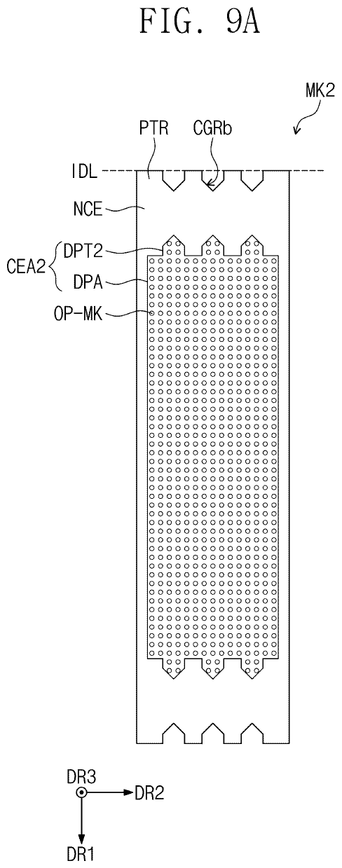

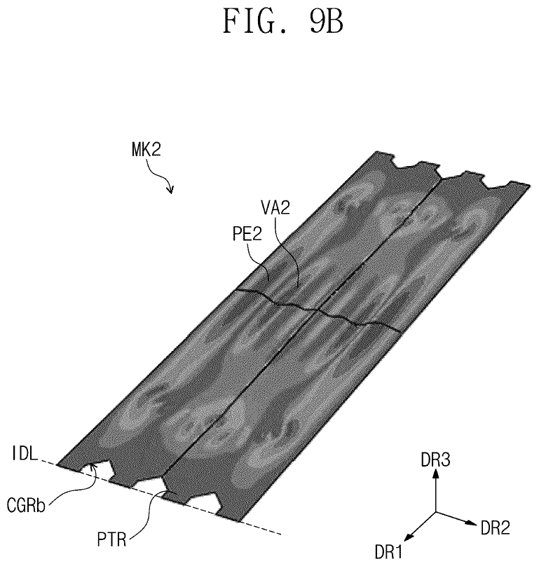

The clamp grooves CGR may extend from both ends of the mask MK toward the center of the mask MK in the first direction DR1. For example, when viewed on a plane, the clamp grooves CGR may have a shape corresponding to a portion of a circle. For example, inner surface of the mask MK, which defines the clamp grooves CGR, may have curved surfaces which are concave toward the center. However, the shape of the clamp grooves CGR is not limited thereto. The shape of the clamp grooves CGR will be described in detail with reference to FIGS. 7A and 9A.

Referring to FIGS. 3 and 4, when viewed on a plane, deposition parts DPA and DPA1 may each have a rectangular shape defined by the first direction DR1 and the second direction DR2. Dummy parts DPT may be disposed adjacent to at least one side of the two sides of the deposition part DPA or DPA1 which are opposite to each other in the first direction DR1. For example, as illustrated in FIG. 3, the dummy parts DPT may be disposed adjacent to the two sides of the deposition part DPA facing the clamp grooves CGR. The dummy parts DPT may extend in the first direction DR1 from the two sides of the deposition part DPA facing the clamp grooves CGR.

However, an embodiment of the invention is not limited thereto. As illustrated in FIG. 4, when the plurality of deposition parts DPA1 are arranged in the first direction DR1, the dummy parts DPT may be disposed adjacent to one side among the two sides opposite to each other in the first direction DR1, of the deposition parts DPA1. The dummy parts DPT may not be disposed on the other side among the two side of the deposition parts DPA1. A peripheral region NCE may be disposed between the deposition parts DPA1 adjacent to each other in the first direction DR1. The one side among the two sides, opposite to each other in the first direction DR1, of the deposition parts DPA1 may be defined as a side facing the clamp grooves CGR.

When viewed on a plane, the dummy parts DPT may each be arranged in the first direction DR1 together with the corresponding clamp groove CGR among the clamp grooves CGR. When viewed on a plane, the dummy parts DPT may each face the corresponding clamp groove CGR among the clamp grooves CGR in the first direction DR1.

The number of dummy parts DPT may be the same as the number of the clamp grooves CGR. For example, three dummy parts DPT in FIG. 3 may be arranged in the second direction DR2. Intervals between the dummy parts DPT adjacent to each other in the second direction DR2 may be uniform.

When viewed on a plane (i.e., in a plan view), the shape of each of the dummy parts DPT may correspond to the shape of the corresponding clamp groove CGR among the clamp grooves CGR. When viewed on a plane, the shapes of the dummy parts DPT may be symmetrical to the shapes of the clamp grooves CGR with respect to the second direction DR2.

In an embodiment, for example, when viewed on a plane, the dummy parts DPT may have a convex shape toward the clamp grooves CGR. When viewed on a plane, inner surfaces of the peripheral region NCE, which define the clamp grooves CGR, may have a shape corresponding to an outer surface of the dummy parts DPT.

When viewed on a plane, a first imaginary lines IDL may extend in the second direction DR2, and connect ends of the protrusions PTR adjacent to each other in the second direction DR2. Hereinafter, the clamp grooves CGR may be defined as regions closed by the first imaginary lines IDL and the protrusions PTR.

When viewed on a plane, a ratio of an area of the dummy parts DPT to an area of the clamp grooves CGR may be about 0.95 to about 1.05. For example, the area of each of the clamp grooves CGR may be the same as the area of a corresponding dummy part DPT among the dummy parts DPT.

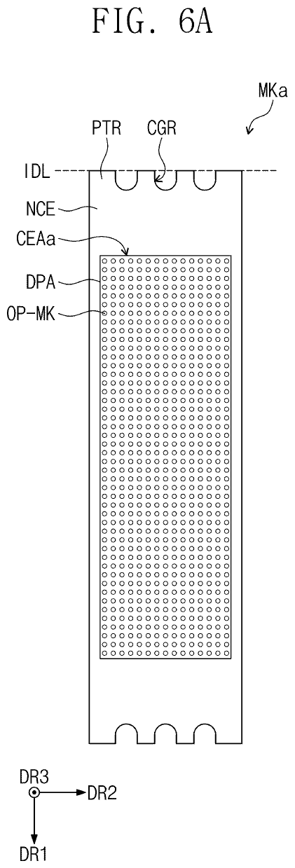

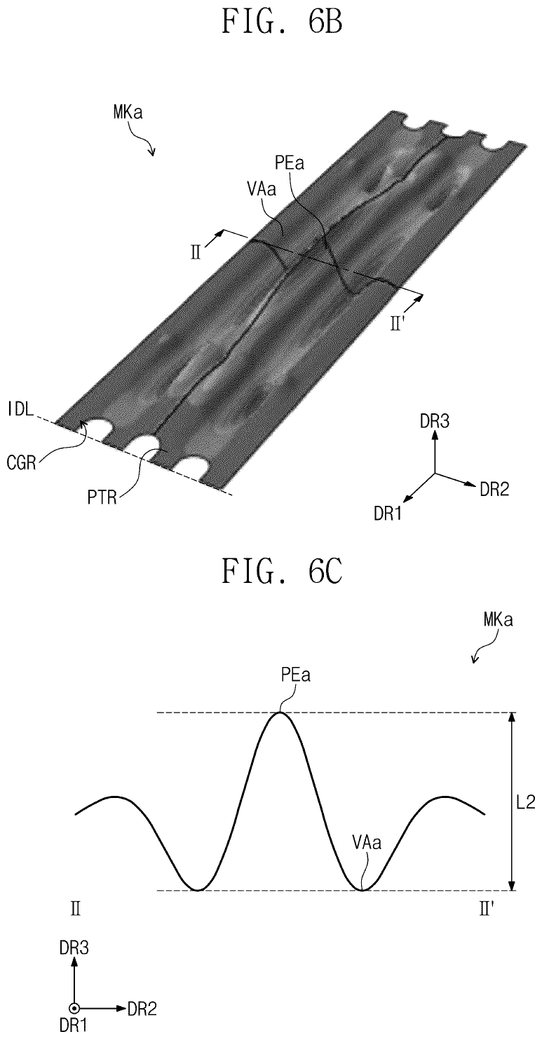

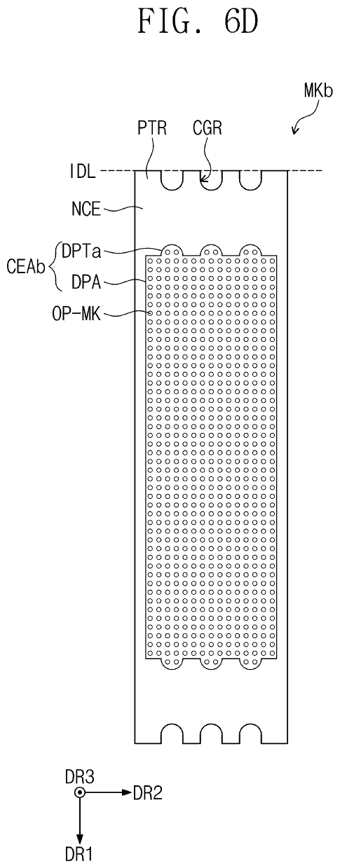

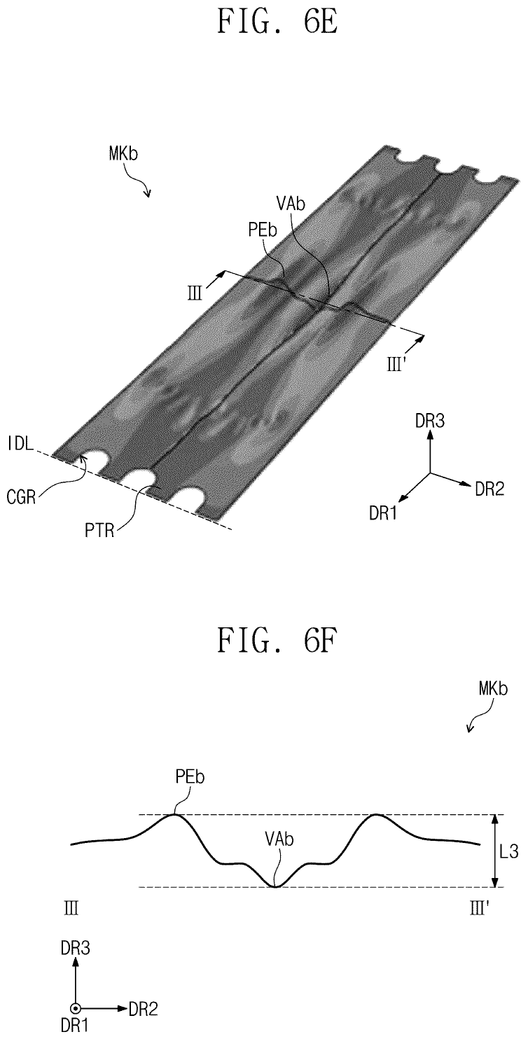

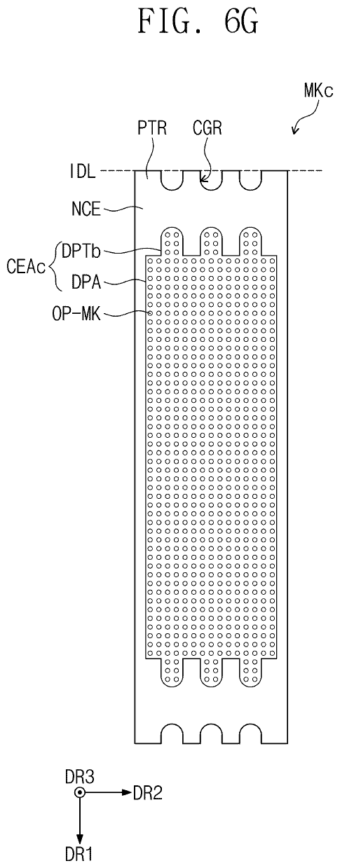

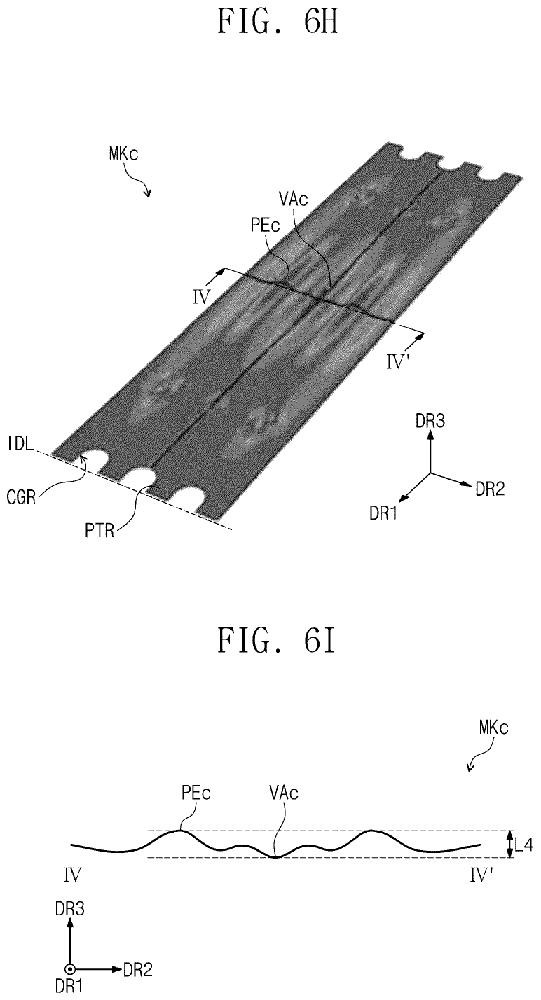

FIG. 5A illustrates that the mask illustrated in FIG. 3 has been deformed. FIG. 5B is a cross-sectional view taken along line I-I′ illustrated in FIG. 5A. FIGS. 6A to 6I are views illustrating masks according to Comparative Examples.

In an embodiment, for example, FIGS. 6A, 6D, and 6G are plan views. FIGS. 6C, 6F, and 6I are cross-sectional views.

In an embodiment, for example, FIG. 6C is a cross-sectional view taken along line II-II′ of FIG. 6B, FIG. 6F is a cross-sectional view taken along line III-III′ of FIG. 6E, and FIG. 6I is a cross-sectional view taken along line IV-IV′ of FIG. 6H.

In an embodiment, for example, FIGS. 5A, 6B, 6E, and 6H illustrate results obtained by analyzing, with a computer program, the sizes of wrinkles which occur on surfaces of masks MK, MKa, MKb, and MKc when the masks MK, MKa, MKb, and MKc are stretched.

In an embodiment, for example, in FIGS. 5B, 6C, 6F, and 6I, masks MK, MKa, MKb, and MKc are briefly illustrated as lines. The lines illustrated in FIGS. 5B, 6C, 6F, and 6I may correspond to any one of an upper surface, a lower surface, of the mask MK, MKa, MKb, or MKc in a side view, or a plane passing through the center of the mask.

For convenience of explanation, the cell regions CEA (see FIG. 3) may be omitted in FIGS. 5A, 6B, 6E, and 6H.

Since a deposition part DPA, a peripheral region NCE, clamp grooves CGR, protrusions PTR, and a first imaginary line IDL in FIGS. 5A to 6I are the same as the deposition part DPA, the peripheral region NCE, the clamp grooves CGR, the protrusions PTR, and the first imaginary line IDL in FIG. 3, descriptions thereof will be simplified or omitted.

Referring to FIGS. 2A, 5A, and 5B, the mask MK may be stretched when the mask MK is connected to the upper surface of the mask frame MF. The mask MK may be stretched in the first direction DR1 and in the opposite direction of the first direction DR1.

When the mask MK is stretched, the mask MK may be deformed. An upper surface and a lower surface of the mask MK may not be flat. As illustrated in FIG. 5B, the upper surface and the lower surface of the mask MK may include curved surfaces. Wrinkles may occur on the upper surface and the lower surface of the mask MK.

Referring to FIGS. 5A and 5B, in the upper surface of the mask MK, a portion of the upper surface of the mask MK which protrudes more upwards than the surroundings may be defined as a peak portion PE. In the upper surface of the mask MK, a portion of the upper surface of the mask MK which is recessed more than the surroundings may be defined as a recessed portion VA. For example, a first length L1 defined by a difference between the height of the peak portion PE and the height of the recessed portion VA may be about 27.5 micrometers (μm).

Referring to FIGS. 6A to 6C, a cell region CEAa may not include the dummy parts DPT (see FIG. 3). When viewed on a plane, two sides of a deposition part DPA which are opposite to each other in the first direction DR1 may be straight lines parallel to the second direction DR2.

When a mask MKa in FIG. 6 is stretched and connected to the mask frame MF (see FIG. 2A), an upper surface of the mask MKa may be deformed. As illustrated in FIGS. 6B and 6C, wrinkles may occur on the upper surface of the mask MKa. A second length L2 defined by a difference between the height of a peak portion PEa and the height of a recessed portion VAa in the mask MKa may be about 368.5 μm.

Referring to FIGS. 6D to 6F, a cell region CEAb may include a deposition part DPA and dummy parts DPTa. When viewed on a plane, an area of the dummy parts DPTa may be smaller than an area of clamp grooves CGR. For example, a ratio of the area of the dummy parts DPTa to the area of the clamp grooves CGR may be less than about 0.95.

When a mask MKb is stretched and connected to the mask frame MF (see FIG. 2A), an upper surface of the mask MKb may be deformed. As illustrated in FIGS. 6E and 6F, wrinkles may occur on the upper surface of the mask MKb. A third length L3 defined by a difference between the height of a peak portion PEb and the height of a recessed portion VAb in the mask MKb may be about 143.44 μm.

Referring to FIGS. 6G to 6I, a cell region CEAc may include a deposition part DPA and dummy parts DPTb. When viewed on a plane, an area of the dummy parts DPTb may be greater than an area of clamp grooves CGR. For example, a ratio of the area of the dummy parts DPTb to the area of the clamp grooves CGR may be more than about 1.05.

When a mask MKc is stretched and connected to the mask frame MF (see FIG. 2A), an upper surface of the mask MKc may be deformed. As illustrated in FIGS. 6H and 6I, wrinkles may occur on the upper surface of the mask MKc. A fourth length LA defined by a difference between the height of a peak portion PEc and the height of a recessed portion VAc in the mask MKc may be about 53.4 μm.

Referring to FIGS. 1, 5B, 6C, 6E, and 6F, when the deposition material EV is deposited on the substrate SUB, the substrate SUB may be disposed on the masks MKa, MKb, and MKc. Here, when wrinkles occur on the upper surfaces of the masks MK, MKa, MKb, and MKc, the substrate SUB may not adhere to the upper surfaces of the masks MKa, MKb, and MKc. The substrate SUB and the upper surfaces of the masks MKa, MKb, and MKc may be spaced apart from each other.

Accordingly, the deposition material EV which has passed through the mask openings OP-MK (see FIG. 3) may not be deposited with a uniform size on the substrate SUB. Thus, a deposition defect may occur in a display panel DP (see FIG. 11) which is deposited by a deposition apparatus ED.

However, when the deposition material EV is deposited on the substrate SUB by using the mask MK according to an embodiment of the invention, sizes of wrinkles which occur on the upper surface of the mask MK may be smaller than sizes of wrinkles which occur on the upper surfaces of the masks MKa, MKb, and MKc according to Comparative Examples. The wrinkles which occur on the upper surface of the mask MK may be stretched out flat by magnetic force between the mask MK and the fixing member PP. Accordingly, the substrate SUB may adhere to the mask MK. Thus, the reliability of a deposition process may be improved.

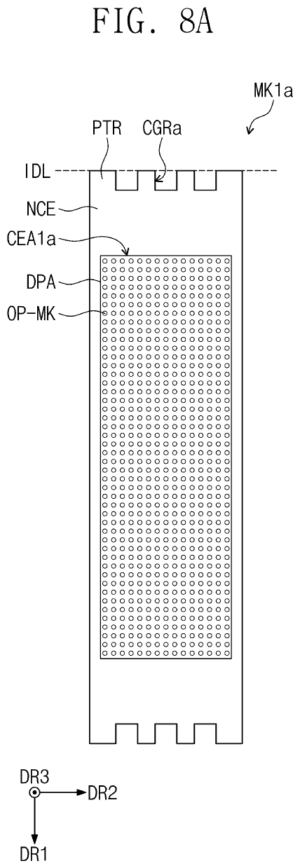

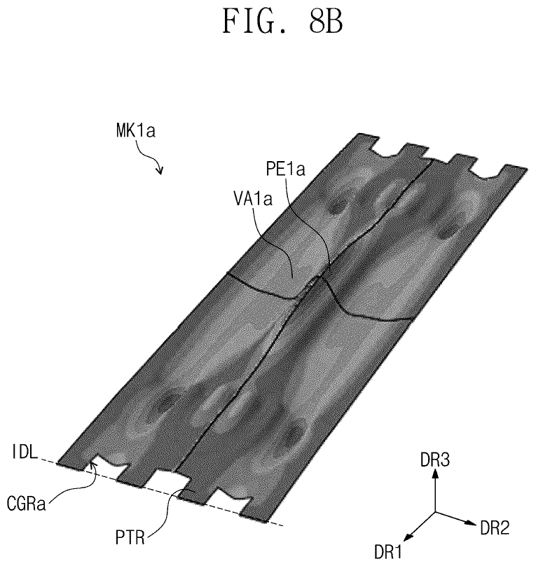

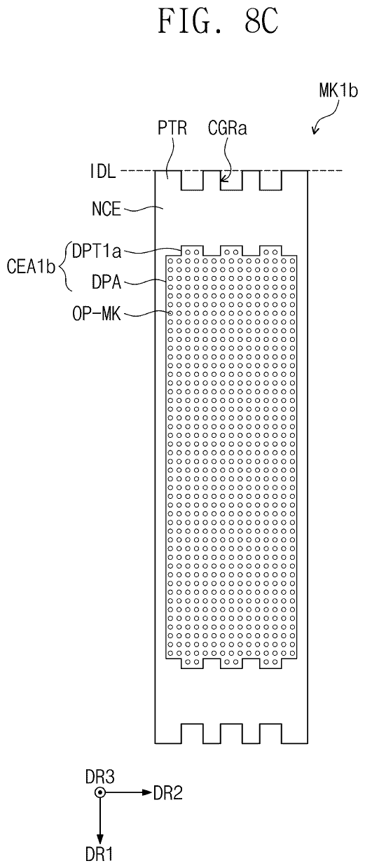

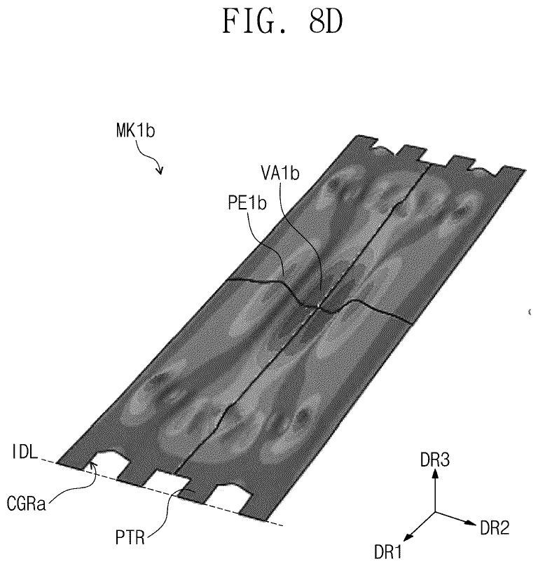

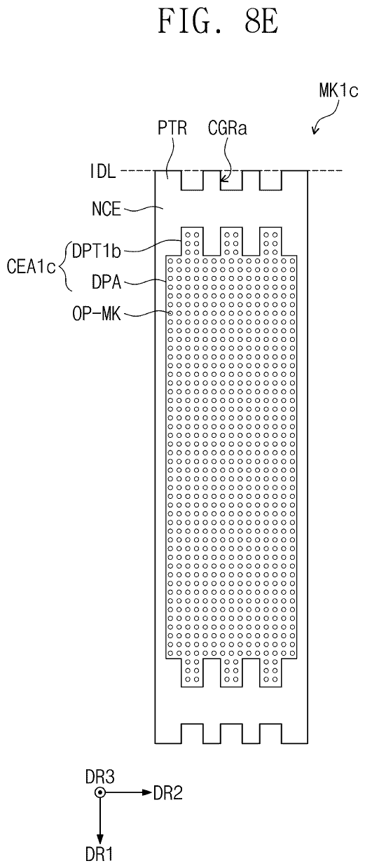

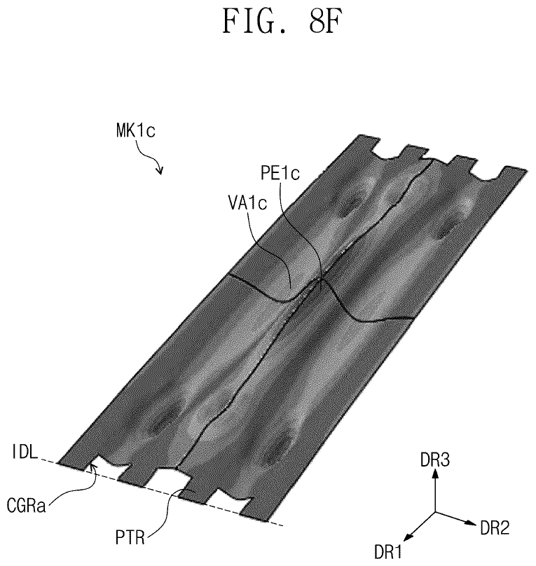

FIGS. 7A and 7B illustrate a mask according to another embodiment of the invention. FIGS. 8A to 8F are views illustrating masks according to Comparative Examples.

In an embodiment, for example, FIGS. 7A, 8A, 8C, and 8E are illustrated as plan views.

In an embodiment, for example, FIGS. 7B, 8B, 8D, and 8F illustrate results obtained by analyzing, with a computer program, the sizes of wrinkles which occur on surfaces of masks MK1, MK1a, MK1b, and MK1c when the masks MK1, MK1a, MK1b, and MK1c are stretched.

For convenience of explanation, cell regions CEA (see FIG. 7A) may be omitted in FIGS. 7B, 8B, 8D, and 8F.

Since a first imaginary line IDL and a deposition part DPA in FIGS. 7A, 8A, 8C, and 8E are the same as the first imaginary line IDL and the deposition part DPA in FIG. 3, descriptions thereof will be omitted or simplified.

Referring to FIGS. 7A and 7B, when viewed on a plane, clamp grooves CGRa may each have a shape corresponding to a portion of a quadrangle. When viewed on a plane, dummy parts DPT1 may have shapes corresponding to the shapes of the clamp grooves CGRa. The dummy parts DPT1 may each have a quadrangular shape.

When the clamp grooves CGRa are defined as regions closed by protrusions PTR and the first imaginary line IDL, a ratio of an area of the dummy parts DPT1 to an area of the clamp grooves CGRa may be about 0.95 to about 1.05. For example, the area of the clamp grooves CGRa and the area of the dummy parts DPT1 may be the same. The area of each of the clamp grooves CGRa may be the same as the area of a corresponding dummy part DPT1 among the dummy parts DPT1.

When the mask MK1 is connected to the upper surface of the mask frame MF (see FIG. 2A), the mask MK1 may be stretched. The mask MK1 may be stretched in the first direction DR1 and in the opposite direction of the first direction DR1.

As illustrated in FIG. 7B, when the mask MK1 is stretched, the mask MK1 may be deformed. An upper surface and a lower surface of the mask MK1 may not be flat. As illustrated in FIG. 7B, the upper surface of the mask MK1 may include a curved surface. Wrinkles may occur on the upper surface of the mask MK1. For example, a difference between the height of a peak portion PE1 and the height of a recessed portion VA1 in the mask MK1 may be about 161.21 μm.

Referring to FIGS. 8A and 8B, a cell region CEA1a may not include the dummy parts DPT1 (see FIG. 7A). When viewed on a plane, two sides of the deposition part DPA which are opposite to each other in the first direction DR1 may be straight lines parallel to the second direction DR2.

When the mask MK1a in FIG. 8A is stretched and connected to the mask frame MF (see FIG. 2A), an upper surface of the mask MK1a may be deformed. As illustrated in FIG. 8B, wrinkles may occur on the upper surface of the mask MK1a. A difference between the height of a peak portion PE1a and the height of a recessed portion VA1a may be about 354.1 μm.

Referring to FIGS. 8C and 8D, a cell region CEA1b may include dummy parts DPT1a and a deposition part DPA. An area of the dummy parts DPT1a may be smaller than an area of clamp grooves CGRa. For example, a ratio of the area of the dummy parts DPT1a to the area of the clamp grooves CGRa may be less than about 0.95.

When the mask MK1b is stretched and connected to the mask frame MF (see FIG. 2A), an upper surface of the mask MK1b may be deformed. As illustrated in FIG. 8D, wrinkles may occur on the upper surface of the mask MK1b. A difference between the height of a peak portion PE1b and the height of a recessed portion VA1b in the mask MK1b may be about 201.39 μm.

Referring FIGS. 8E and 8F, a cell region CEA1c may include dummy parts DPT1b and a deposition part DPA. An area of the dummy parts DPT1b may be greater than an area of clamp grooves CGRa. For example, a ratio of the area of the dummy parts DPT1b to the area of the clamp grooves CGRa may be more than about 1.05.

When the mask MK1c is stretched and connected to the mask frame MF (see FIG. 2A), an upper surface of the mask MK1c may be deformed. As illustrated in FIG. 8F, wrinkles may occur on the upper surface of the mask MK1c. A difference between the height of a peak portion PE1c and the height of a recessed portion VA1c in the mask MK1c may be about 394.4 μm.

Referring to FIGS. 7B, 8B, 8D, and 8F, a size of wrinkles which occur on the upper surface of the mask MK1 in FIG. 7B may be smaller than a size of wrinkles which occur on the upper surfaces of the masks MK1a, MK1b, and MK1c in FIGS. 8B, 8D, and 8F. Accordingly, when a deposition process proceeds while using the mask MK1 in FIG. 7B, a distance between the substrate SUB and the upper surface of the mask MK1 may be effectively reduced. Thus, the deposition material EV may be deposited with a uniform size on the substrate SUB, and the reliability of the process may be improved.

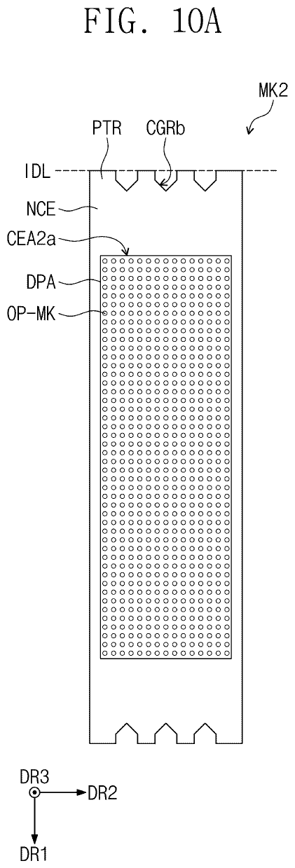

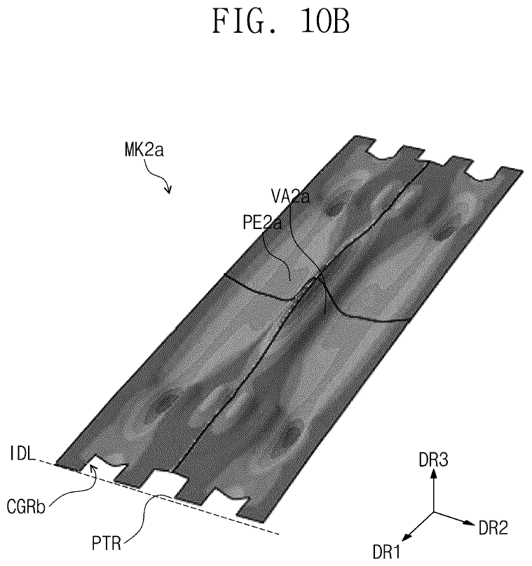

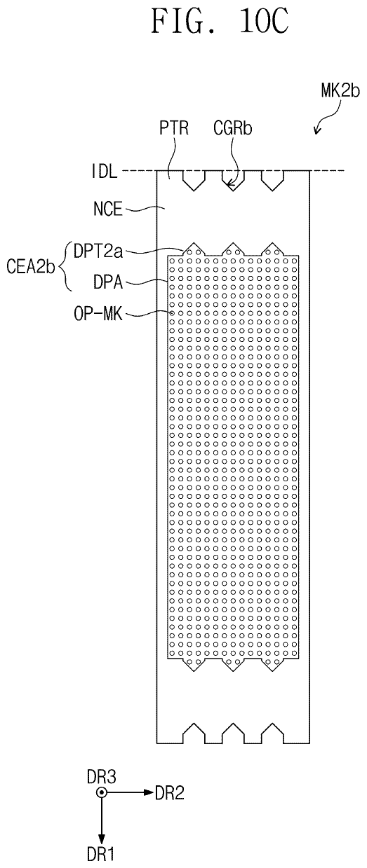

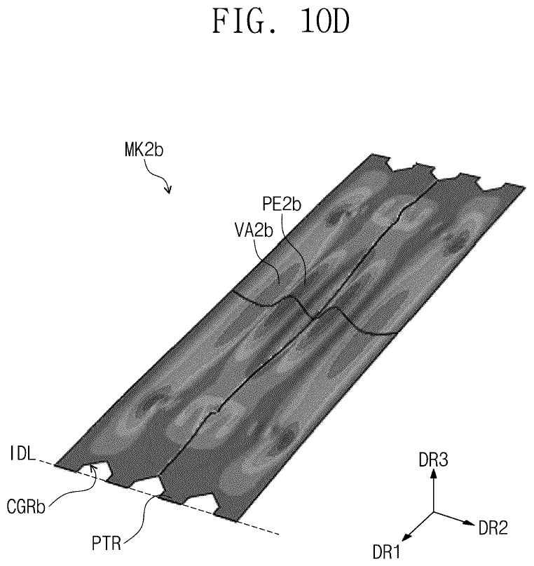

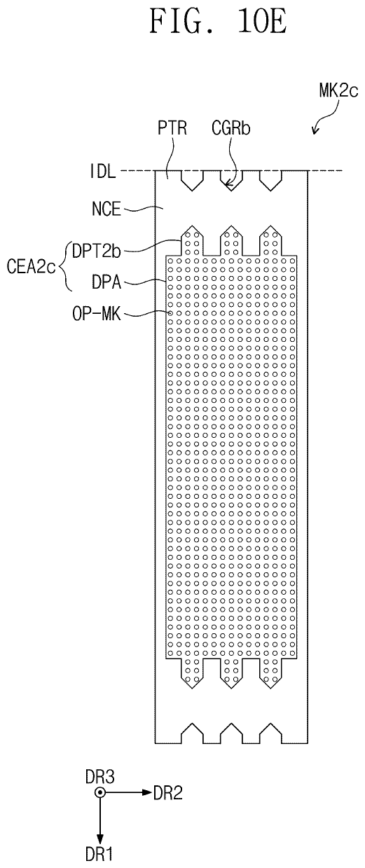

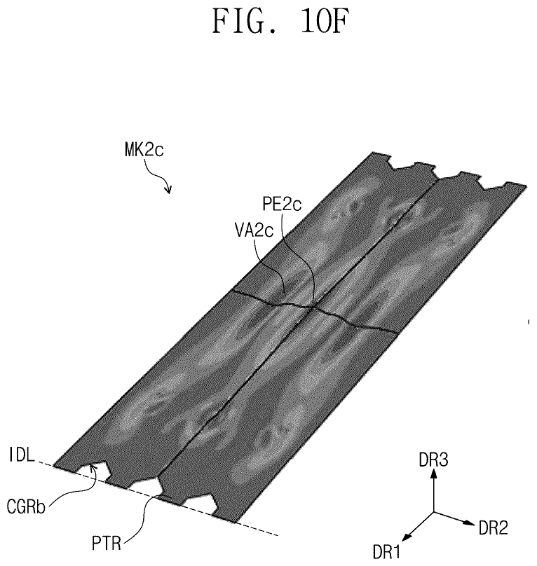

FIGS. 9A and 9B illustrate a mask according to another embodiment of the invention. FIGS. 10A to 10F are views illustrating masks according to Comparative Examples.

In an embodiment, for example, FIGS. 9A, 10A, 10C, and 10E are illustrated as plan views.

In an embodiment, for example, FIGS. 9B, 10B, 10D, and 10F illustrate results obtained by analyzing, with a computer program, the sizes of wrinkles which occur on surfaces of masks MK2, MK2a, MK2b, and MK2c when the masks MK2, MK2a, MK2b, and MK2c are stretched.

For convenience of explanation, cell regions CEA (see FIG. 9A) may be omitted in FIGS. 9B, 10B, 10D, and 10F.

Since a peripheral region NCE, a first imaginary line IDL, and a deposition part DPA in FIGS. 9A, 10A, 10C, and 10E are the same as the peripheral region NCE, the first imaginary line IDL, and the deposition part DPA in FIG. 3, descriptions thereof will be omitted or simplified.

Referring to FIGS. 9A and 9B, when viewed on a plane, for example, clamp grooves CGRb may each have a shape corresponding to a portion of a pentagon. However, an embodiment of the invention is not limited thereto, and the clamp grooves CGRb may each have a shape corresponding to a portion of another polygon.

When viewed on a plane, dummy parts DPT2 may have shapes corresponding to the clamp grooves CGRb. For example, the dummy parts DPT2 may each have a pentagonal shape.

A ratio of an area of the dummy parts DPT2 to an area of the clamp grooves CGRb, which are defined as regions closed by protrusions PTR and the first imaginary line IDL, may be about 0.95 to about 1.05. For example, the area of the clamp grooves CGRb and the area of the dummy parts DPT2 may be the same. The area of each of the clamp grooves CGRb may be the same as the area of a corresponding dummy part DPT2 among the dummy parts DPT2.

When the mask MK2 is connected to the upper surface of the mask frame MF (see FIG. 2A), the mask MK2 may be stretched. The mask MK2 may be stretched in the first direction DR1 and in the opposite direction of the first direction DR1.

When the mask MK2 is stretched, the mask MK2 may be deformed. An upper surface and a lower surface of the mask MK2 may not be flat. As illustrated in FIG. 9B, the upper surface of the mask MK2 may include a curved surface. Wrinkles may occur on the upper surface of the mask MK2. For example, a difference between the height of a peak portion PE2 and the height of a recessed portion VA2 in the mask MK2 may be about 76.71 μm.

Referring to FIGS. 10A and 10B, a cell region CEA2a may not include the dummy parts DPT2 (see FIG. 9A). When viewed on a plane, two sides of a deposition part DPA which are opposite to each other in the first direction DR1 may be straight lines parallel to the second direction DR2.

When the mask MK2a in FIG. 10A is stretched and connected to the mask frame MF (see FIG. 2A), an upper surface of the mask MK2a may be deformed. As illustrated in FIG. 10B, wrinkles may occur on the upper surface of the mask MK2a. A difference between the height of a peak portion PE2a and the height of a recessed portion VA2a in the mask MK2a may be about 196.58 μm.

Referring to FIGS. 10C and 10D, a cell region CEA2b may include dummy parts DPT2a and a deposition part DPA. An area of the dummy parts DPT2a may be smaller than an area of clamp grooves CGRb. For example, a ratio of the area of the dummy parts DPT2a to the area of the clamp grooves CGRb may be less than about 0.95.

When the mask MK2b is stretched and connected to the mask frame MF (see FIG. 2A), an upper surface of the mask MK2b may be deformed. As illustrated in FIG. 10D, wrinkles may occur on the upper surface of the mask MK2b. A difference between the height of a peak portion PE2b and the height of a recessed portion VA2b may be about 196.58 μm.

Referring to FIGS. 10E and 10F, a cell region CEA2c may include dummy parts DPT2b and a deposition part DPA. An area of the dummy parts DPT2b may be greater than an area of clamp grooves CGRb. For example, a ratio of the area of the dummy parts DPT2b to the area of the clamp grooves CGRb may be more than about 1.05.

When the mask MK2c is stretched and connected to the mask frame MF (see FIG. 2A), an upper surface of the mask MK2c may be deformed. As illustrated in FIG. 10F, wrinkles may occur on the upper surface of the mask MK2c. A difference between the height of a peak portion PE2c and the height of a recessed portion VA2c in the mask MK2c may be about 394.4 μm.

Referring to FIGS. 9B, 10B, 10D, and 10F, a size of wrinkles which occur on the upper surface of the mask MK2 in FIG. 9B may be smaller than a size of wrinkles which occur on the upper surfaces of the masks MK2a, MK2b, and MK2c in FIGS. 10B, 10D, and 10F. Accordingly, when a deposition process proceeds while using the mask MK2 in FIG. 9B, a distance between the substrate SUB and the upper surface of the mask MK2 may be effectively reduced. Thus, the deposition material EV may be deposited with a uniform size on the substrate SUB, and the reliability of the process may be improved.

FIG. 11 is a plan view of a display panel manufactured using the mask assembly illustrated in FIG. 2A.

Referring to FIG. 11, a display panel DP may have a rectangular shape having short sides extending in a first direction DR1 and long sides extending in a second direction DR2, but the shape of the display panel DP is not limited thereto. The display panel DP may include a display part DA and a non-display part NDA surrounding the display part DA.

The display panel DP may be a light-emitting display panel. The display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like. Hereinafter, the display panel DP will be described as an organic light-emitting display panel.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power supply lines PLL1 and PLL2, connection lines CNL, and a plurality of pads PD. m and n are natural numbers.

The pixels PX may be disposed in the display part DA. A scan driver SDV and a light emission driver EDV may be disposed in the non-display part NDA adjacent to the respective long sides of the display panel DP. A data driver DDV may be disposed in the non-display part NDA adjacent to any one of the short sides of the display panel DP. When viewed on a plane, the data driver DDV may be adjacent to a lower end of the display panel DP.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in the first direction DR1 and may be connected to the pixels PX and the light emission driver EDV.

The first power supply line PLL1 may extend in the second direction DR2 and may be disposed in the non-display part NDA. The first power supply line PLL1 may be disposed between the display part DA and the light emission driver EDV. However, an embodiment of the invention is not limited thereto, and the first power supply line PLL1 may be disposed between the display part DA and the scan driver SDV in another embodiment.

The connection lines CNL may extend in the first direction DR1 and may be arranged in the second direction DR2. The connection lines CNL may be connected to the first power supply line PLL1 and the pixels PX. A first voltage may be applied to the pixels PX through the first power supply line PLL1 and the connection lines CNL which are connected to each other.

The second power supply line PLL2 may be disposed in the non-display part NDA. The second power supply line PLL2 may extend along the long sides of the display panel DP and the other short side of the display panel DP, where the data driver DDV is not disposed. The second power supply line PLL2 may be disposed outside the scan driver SDV and the light emission driver EDV.

Although not illustrated, the second power supply line PLL2 may extend toward the display part DA and may be connected to the pixels PX. A second voltage having a lower level than the first voltage may be applied to the pixels PX through the second power supply line PLL2.

The first control line CSL1 may be connected to the scan driver SDV, and when viewed on a plane, the first control line CSL1 may extend toward the lower end of the display panel DP. The second control line CSL2 may be connected to the light emission driver EDV, and when viewed on a plane, the second control line CSL2 may extend toward the lower end of the display panel DP. The data driver DDV may be disposed between the first control line CSL1 and the second control line CSL2.

The pads PD may be disposed on the display panel DP. The pads PD may be more adjacent to the lower end of the display panel DP than the data driver DDV. The data driver DDV, the first power supply line PLL1, the second power supply line PLL2, the first control line CSL1, and the second control line CSL2 may be connected to the pads PD. The data lines DL1 to DLn may be connected to the data driver DDV, and the data driver DDV may be connected to the pads corresponding to the data lines DL1 to DLn.

Light-emitting elements of the display panel DP may be formed by the cell regions CEA which are illustrated in FIGS. 2A and 2B.

Unit regions corresponding to such a display panel DP may be defined in the substrate SUB. The light-emitting elements are disposed in the unit regions, and then the unit regions may be cut. Thus, the display panel DP illustrated in FIG. 11 may be manufactured.

Although not illustrated, a timing controller for controlling operations of the scan driver SDV, the data driver DDV, and the light emission driver EDV and a voltage generator for generating the first and second voltages may be disposed on a printed circuit board. The timing controller and the voltage generator may be connected to the corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light-emitting signals, and the light-emitting signals may be applied to the pixels PX through the emission lines EL1 to ELm.

The pixels PX may receive the data voltages in response to the scan signals. The pixels PX may display images by emitting light with a luminance corresponding to the data voltages in response to the light-emitting signals. The emission time of the pixels PX may be controlled by the light-emitting signals.

The wiring may include the data lines DL1 to DLn. The pads connected to the wiring may include the pads PD illustrated in FIG. 11. The display panel DP on which light-emitting layers of the pixels PX are not formed may be defined as the substrate SUB.

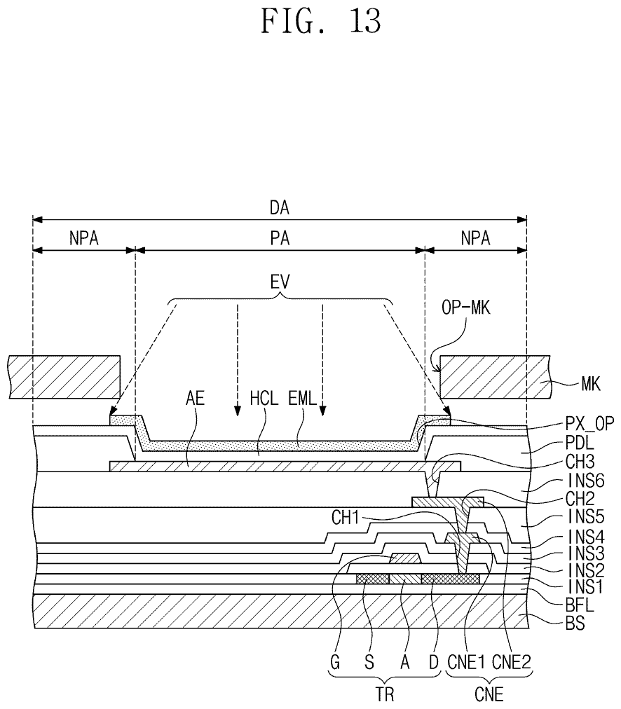

A cross-sectional structure of the substrate SUB, on which the light-emitting layers are not formed, will be described below in FIG. 13. The pads PD may be disposed in the substrate SUB, and the substrate SUB may be defined as a state in which the printed circuit board is not connected. The pads PD may be connected to the ground terminal GND, and the pads PD and the data lines DL1 to DLn may be earthed.

FIG. 12 exemplarily illustrates a cross-section of one pixel illustrated in FIG. 11.

Referring to FIGS. 11 and 12, a pixel PX may be disposed on a base substrate BS, and may include a transistor TR and a light-emitting element OLED. The transistors TR and the light-emitting elements OLED of the pixels PX may be connected to the data lines DL1 to DLn and the first and second power supply lines PLL1 and PLL2, which are described above.

The transistors TR and the light-emitting elements OLED of the pixels PX may be connected to the pads PD in FIG. 11 through the data lines DL1 to DLn (see FIG. 11) and the first and second power supply lines PLL1 and PLL2 (see FIG. 11).

The light-emitting element OLED may include a first electrode AE, a second electrode CE, a hole control layer HCL, an electron control layer ECL, and a light-emitting layer EML. The first electrode AE may be an anode, and the second electrode CE may be a cathode.

The transistor TR and the light-emitting element OLED may be disposed on the base substrate BS. One transistor TR is exemplarily illustrated, but the pixel PX may substantially include a plurality of transistors and at least one capacitor for driving the light-emitting element OLED.

A display part DA may include a light-emitting part PA corresponding to the pixel PX and a non-light emitting part NPA around the light-emitting part PA. The light-emitting element OLED may be disposed in the light-emitting part PA.

The base substrate BS may include a flexible plastic substrate. For example, the base substrate BS may include transparent polyimide (PI). A buffer layer BFL may be disposed on the base substrate BS, and the buffer layer BFL may be an inorganic layer.

A semiconductor pattern may be disposed on the buffer layer BFL. The semiconductor pattern may include polysilicon. However, an embodiment of the invention is not limited thereto, and the semiconductor pattern may also include amorphous silicon or a metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may substantially serve as a source electrode and a drain electrode of the transistor TR. The lightly doped region may substantially correspond to an active (or a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light-emitting element OLED, and may connect the transistor TR and the light-emitting element OLED. The connection electrode CNE may include a first connection electrode CNE1 and a second connection electrode CNE2.

The first connection electrode CNE1 may be disposed on the third insulating layer INS3, and may be connected to the drain D through a first contact hole CH1 which is defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 which is defined in the fifth insulating layer INS5. A sixth insulating layer INS6 may be disposed on the second connection electrode CNE2. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a third contact hole CH3 which is defined in the sixth insulating layer INS6. A pixel-defining film PDL exposing a predetermined portion of the first electrode AE may be disposed on the first electrode AE and the sixth insulating layer INS6. An opening PX_OP for exposing a predetermined portion of the first electrode AE may be defined in the pixel-defining film PDL.

The hole control layer HCL may be disposed on the first electrode AE and the pixel-defining film PDL. The hole control layer HCL may be disposed in the light-emitting part PA and the non-light emitting part NPA in common. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate any one light among red light, green light, and blue light.

The electron control layer ECL may be disposed on the light-emitting layer EML and the hole control layer HCL. The electron control layer ECL may be disposed in the light-emitting part PA and the non-light emitting part NPA in common. The electron control layer ECL may include an electron transport layer and an electron injection layer.

The second electrode CE may be disposed on the electron control layer ECL. The second electrode CE may be disposed in the pixels PX in common. Layers from the buffer layer BFL to the light-emitting element OLED may be defined as a pixel layer PXL.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers and an organic layer between the inorganic layers. The inorganic layer may protect the pixel PX from moisture/oxygen. The organic layer may protect the pixel PX from foreign matters such as dust particles.

A first voltage may be applied to the first electrode AE through the transistor TR, and a second voltage having a lower level than the first voltage may be applied to the second electrode CE. Holes and electrons injected into the light-emitting layer EML combine to form excitons, and when the excitons transition to a ground state, the light-emitting element OLED may emit light.

FIG. 13 illustrates a deposition process illustrated in FIG. 1.

Referring to FIGS. 1, 12, and 13, layers from a base substrate BS to a layer on which a first electrode AE is disposed may be defined as a substrate SUB. As described above, the transistor TR may be connected to the pads PD through the data lines DL1 to DLn. That is, the substrate SUB may include the data lines DL1 to DLn, which are defined as the wiring, and the pads PD connected to the data lines DL1 to DLn.

A mask MK may be disposed to face the substrate SUB. The mask MK may be disposed to be close to the substrate SUB. A deposition material EV may be provided onto the substrate SUB through a mask opening OP-MK which is defined in an upper surface of the mask MK. A light-emitting layer EML may be disposed on the substrate SUB by the deposition material EV.

According to an embodiment of the invention, a mask may include dummy parts. When viewed on a plane, a shape of the dummy part may correspond to a shape of each of clamp grooves which are defined in both ends of the mask. An area of the dummy part may be the same as an area of the clamp grooves which are defined as regions closed by an imaginary line connecting ends of the mask. Accordingly, when the mask is stretched, the size of wrinkles, which occur on an upper surface of the mask, may be effectively reduced. Thus, the reliability of a deposition process may be improved.

In the above, description has been made with reference to embodiments, but those skilled in the art or those of ordinary skill in the relevant technical field may understand that various modifications and changes may be made to the invention within the scope not departing from the spirit and the technology scope of the invention described in the claims to be described later. In addition, embodiments disclosed in the invention are not intended to limit the technical spirit of the invention, and all technical ideas within the scope of the following claims and their equivalents should be construed as being included in the scope of the invention.

What is claimed is:

1. A mask assembly comprising:
a mask frame having a frame opening defined therein; and
a mask disposed on an upper surface of the mask frame, and in which a clamp groove is defined in at least one of two sides opposite to each other in a first direction,
wherein the mask includes
a cell region having a deposition part and a dummy part extending in the first direction from the deposition part toward the clamp groove, and
a peripheral region surrounding the cell region and having the clamp groove defined therein, and
wherein an inner surface of the peripheral region, which defines the clamp groove, has a shape corresponding to an outer surface of the dummy part.

2. The mask assembly of claim 1, wherein in a plan view, a shape of the dummy part corresponds to a shape of the clamp groove.

3. The mask assembly of claim 2, wherein in the plan view, the shape of the clamp groove is symmetrical to the shape of the dummy part with respect to the first direction.

4. The mask assembly of claim 3, wherein in the plan view, the clamp groove has a shape corresponding to a portion of a circle.

5. The mask assembly of claim 3, wherein when in the plan view, the clamp groove has a shape corresponding to a portion of a polygon.

6. The mask assembly of claim 1, wherein a plurality of mask openings are defined in the deposition part and the dummy part, and the mask openings overlap the frame opening in the plan view.

7. The mask assembly of claim 1, further comprising:
a first rod disposed between the mask frame and the mask and extending in the first direction; and
a second rod disposed between the mask frame and the mask, and extending in a second direction crossing the first direction.

8. The mask assembly of claim 7, wherein the second rod overlaps the dummy part in a plan view.

9. The mask assembly of claim 7, wherein in a plan view, the mask frame has a shape of a quadrangular frame, which has short sides extending in the first direction and long sides extending in the second direction,
the first rod is disposed in a first groove, which is defined in the upper surface of the mask frame adjacent to the long sides, and
the second rod is disposed in a second groove, which is defined in the upper surface of the mask frame adjacent to the short sides.

10. The mask assembly of claim 1, wherein each of the clamp groove and the dummy part is provided in plurality, and
a total number of the clamp grooves is the same as a total number of the dummy parts.

11. The mask assembly of claim 1, wherein the mask and the mask frame comprise Invar.

12. A mask assembly comprising:
a mask frame having a frame opening defined therein; and
a mask disposed on an upper surface of the mask frame, and including a plurality of protrusions disposed on at least one of two sides opposite to each other in a first direction,
wherein the mask includes
a deposition part,
a dummy part extending from at least one of the two sides of the deposition part opposite to each other in the first direction, and
a peripheral region surrounding the deposition part and the dummy part, and
wherein a clamp groove is defined between the protrusions arranged in a second direction crossing the first direction, and a ratio of an area of the dummy part to an area of the clamp groove, which is defined as a region closed by a first imaginary line extending in the second direction and connecting ends of the protrusions, is about 0.95 to about 1.05 in a plan view.

13. The mask assembly of claim 12, wherein the clamp groove has a shape corresponding to the dummy part in the plan view.

14. The mask assembly of claim 13, wherein in the plan view, the shape of the clamp groove is symmetrical to a shape of the dummy part with respect to the first direction.

15. The mask assembly of claim 13, wherein in the plan view, the dummy part has a shape corresponding to a portion of a circle.

16. The mask assembly of claim 13, wherein in the plan view, the dummy part has a shape corresponding to a portion of a polygon.

17. The mask assembly of claim 12, wherein each of the clamp groove and the dummy part is provided in plurality, and
a total number of the clamp grooves is the same as a total number of the dummy parts.

18. The mask assembly of claim 12, further comprising:
a first rod disposed between the mask frame and the mask, and extending in the first direction; and
a second rod disposed between the mask frame and the mask, and extending in a second direction crossing the first direction,
wherein the dummy part overlaps the second rod in the plan view.

19. The mask assembly of claim 18, wherein a plurality of mask openings are defined in the dummy part and the deposition part, the mask openings are arranged in the first direction and the second direction, and the mask openings overlap the frame opening in the plan view.

20. The mask assembly of claim 12, further comprising a plurality of alignment rods disposed on the upper surface of the mask frame,
wherein the mask is disposed between the alignment rods which are adjacent to each other in the second direction.
